(19) United States
(12) Patent Application Publication
(10) Pub. No.: US 2008/0170372 A1
(43) Pub. Date: Jul. 17, 2008

(54) Electronic control apparatus and method of manufacturing the same

(75) Inventor: Masato Kirigaya, Okazaki-city (JP)

Correspondence Address: POSZ LAW GROUP, PLC, 12040 SOUTH LAKES DRIVE, SUITE 101, RESTON, VA, 20191, US

(73) Assignee: Denso Corporation, Kariya-city (JP)

(21) Appl. No.: 12/003,871

(22) Filed: Jan. 3, 2008

(30) Foreign Application Priority Data
Jan. 15, 2007 (JP) 2007-6359

(51) Int. Cl. H05K 7/20; H05K 3/00

(52) U.S. Cl. 361/720; 29/829

(57) ABSTRACT

An electronic control apparatus includes a circuit board with a circuit element mounted thereon, a heatsink for dissipating heat from the circuit board placed thereon, an external terminal having a first end electrically connected to the circuit board and a second end connectable to an external device, a molding resin for covering the circuit board and the first end of the external terminal. The second end of the external terminal is exposed outside the molding resin. The heatsink is at least partially covered with the molding resin. At least one of covered surfaces of the circuit board and the heatsink is at least partially roughened to have a predetermined surface roughness, which allows the circuit board and the heatsink to be tightly attached to the molding resin.

### CROSS REFERENCE TO RELATED APPLICATION

This application is based on and incorporates herein by reference Japanese Patent Application No. 2007-6359 filed on Jan. 15, 2007.

### FIELD OF THE INVENTION

The present invention relates to an electronic control apparatus and a method of manufacturing the electronic control apparatus.

### BACKGROUND OF THE INVENTION

As disclosed, for example, in JP-A-2006-41071, an electronic control apparatus has been proposed that is designed to be installed in a hostile environment such as an engine room or a transmission unit of a vehicle to control an engine or an automatic transmission of the vehicle.

The electronic control apparatus disclosed in JP-A-2006-41071 (especially, FIG. 8) has a full mold structure. Specifically, an electronic device is mounted on a circuit board through an electrically conducting material such as solder or conductive adhesive. The circuit board is electrically connected to an external terminal through a conductive wire. The circuit board and the external terminal are integrally covered with a molding resin except for a tip portion of the external terminal. Further, surfaces of the electronic device and the circuit board are coated with an electrical insulating material having an elasticity lower than that of each of the conducting material and the molding resin. The insulating material helps prevent the molding resin from being cracked and detached from the circuit board.

For example, polyamide or polyimide is used as the insulating material. The insulating material is diluted with a solvent and then applied to the surfaces of the electronic device and the circuit board, for example, by using a dispenser. Typically, polyamide is diluted with a high polarity solvent. Since such a high polarity solvent can dissolve a resin component (e.g., organic binder) contained in conductive adhesive (e.g., silver paste) used as a conducting material, a junction resistance may increase. Further, since such a high polarity solvent can dissolve a resin package of an electronic device (e.g., tantalum capacitor), a characteristic of the electronic device may change.

Generally, a circuit board is partially warped. Therefore, the insulating material applied to the circuit board may flow away from the warped portion so that the warped portion may not be coated with the insulating material. As a result, the insulating material may not help prevent the molding resin from being cracked and detached from the circuit board.

### SUMMARY OF THE INVENTION

In view of the above-described problem, it is an object of the present invention to provide an electronic control apparatus having a structure for preventing a molding resin from being cracked and detached from a circuit board without affecting a characteristic of a circuit element mounted on the circuit board and a reliability of connection of the circuit element to the circuit board.

An electronic control apparatus includes a circuit board with a circuit element mounted thereon, a heatsink for dissipating heat from the circuit board placed thereon, an external terminal having a first end electrically connected to the circuit board and a second end connectable to an external device, a molding resin for covering the circuit board and the first end of the external terminal. The second end of the external terminal is exposed outside the molding resin. The heatsink is at least partially covered with the molding resin. At least one of covered surfaces of the circuit board and the heatsink is at least partially roughened to have a predetermined surface roughness.

Due to the roughened surface, the molding resin can widely contact the circuit board and the heatsink. Further, the roughened surface can produce anchor effects that cause the circuit board and the heatsink to be anchored to the molding resin. Thus, the circuit board and the heatsink is tightly attached to the molding resin, so that the molding resin can be prevented from being cracked and detached from the circuit board and the heatsink without affecting a characteristic of the circuit element and a reliability of connection of the circuit element to the circuit board.

### BRIEF DESCRIPTION OF THE DRAWINGS

The above and other objectives, features and advantages of the present invention will become more apparent from the following detailed description made with check to the accompanying drawings. In the drawings:

FIG. 1 is a diagram illustrating a plan view of an electronic control apparatus according to a first embodiment of the present invention;

FIG. 2 is a diagram illustrating a cross-sectional view taken along line II-II of FIG. 1;

FIG. 3 is a diagram illustrating a partially enlarged view of FIG. 2;

FIG. 4 is a diagram illustrating a graph representing a relationship between a temperature of a circuit board of the electronic control apparatus of FIG. 1 and a stress exerted on the circuit board;

FIG. 5 is a diagram illustrating a graph representing a relationship between a surface roughness of a heatsink and an adhesion of the heatsink to a molding resin of the electronic control apparatus;

FIG. 6 is a diagram illustrating a cross-sectional view of an electronic control apparatus according to a modification of the first embodiment;

FIG. 7 is a diagram illustrating a back view of a heatsink of the electronic control apparatus of FIG. 6; and

FIG. 8 is a diagram illustrating a partially enlarged cross-sectional view of an electronic control apparatus according to a second embodiment of the present invention.

### DETAILED DESCRIPTION OF THE PREFERRED EMBODIMENTS

### First Embodiment

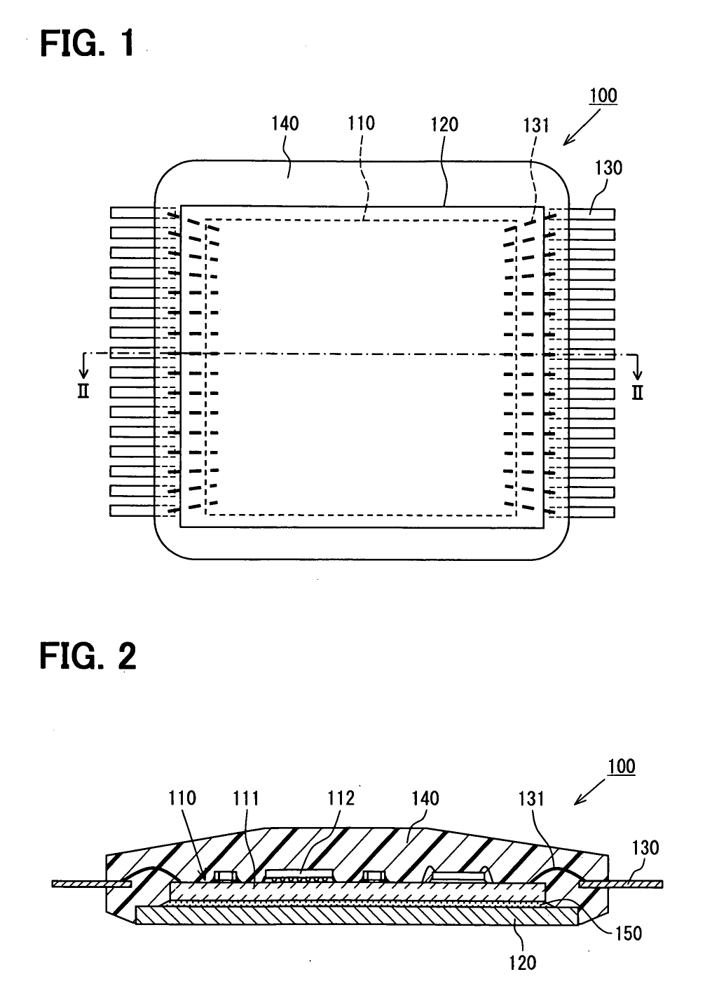

Referring to FIGS. 1, 2, an electronic control apparatus 100 according to a first embodiment of the present invention includes a circuit board 110, a heatsink 120 having a front surface on which the circuit board 110 is mounted, a lead terminal 130 having a first end electrically connected to the circuit board 110, an molding resin 140 for covering the circuit board 110 and the first end of the lead terminal 130. The molding resin 140 is placed on the circuit board 110 in such a manner that the heatsink 120 and the lead terminal 130 are partially exposed outside the molding resin 140. Specifically, as shown in FIG. 2, a back surface of the heatsink 120 and a second end of the lead terminal 130 are exposed from the molding resin 140. For example, the electronic control apparatus 100 may be installed on a vehicle. Specifically, the electronic control apparatus 100 may be used for a automatic transmission. In this case, the electronic control apparatus 100 may be combined with components such as a solenoid valve and a sensor into a single module, and the module is installed in a valve body located inside the automatic transmission.

The circuit board 110 includes a wiring board 111, and a circuit element 112 mounted on the wiring board 111. For example, the wiring board 111 includes a base substrate made of ceramics or resin and a wiring pattern (not shown) formed to the base substrate. For example, the circuit element 112 can include a microprocessor, an integrated circuit (IC), a resistor, and a capacitor, and the like. In the present embodiment, a 35 millimeter (mm) square ceramic multilayer board with an alumina substrate is employed for the wiring board 111. A ceramic multilayer board has a thermal conductivity greater than that of a typical resin board. For example, whereas a ceramic multilayer board has a thermal conductivity of 10 watt per meter Kelvin (W/mK), a typical resin board has a thermal conductivity of 1 W/mK. Therefore, heat dissipation efficiency can be improved by employing a ceramic multilayer board for the wiring board 111.

Further, a ceramic multilayer board has a linear expansion coefficient less than that of a typical resin board. For example, whereas a ceramic multilayer board has a linear expansion coefficient of between 5 and 7 ppm/° C., a typical resin board has a linear expansion coefficient of between 9 and 17 ppm/° C. Since the circuit element 112 has a linear expansion coefficient of, for example, between 3 and 10 ppm/° C., a difference in a linear expansion coefficient between the wiring board 111 and the circuit element 112 can be reduced by employing a ceramic multilayer board for the wiring board 111. Thus, the circuit element 112 can be reliably connected to the wiring board 111.

Further, a ceramic multilayer board has a thermal resistance greater than that of a typical resin board. Therefore, the electronic control apparatus 100 can reliably work even under high temperature conditions by employing a ceramic multilayer board for the wiring board 111.

The circuit element 112 is mechanically, electrically connected to an electrical land (not shown) formed on the wiring board 111 through an electrically conductive member such as solder, conductive adhesive (e.g., silver paste), or the like. In the present embodiment, the circuit element 112 is mechanically, electrically connected to the electrical land on the wiring board 111 through solder such as a lead free solder consisting of 3% silver (Ag), 0.5% copper (Cu), and 96.5% tin (Sn). Heat dissipation efficiency can be improved by using solder to connect the wiring board 111 and the circuit element 112. In contrast, manufacturing steps and cost can be reduced by using conductive adhesive to connect the wiring board 111 and the circuit element 112, because solder requires a cleaning process.

The circuit element 112 is mounted on only a front surface of the wiring board 111. A back surface of the wiring board 111 is fixed to the front surface of the heatsink 120 through an adhesive layer 150. For example, in the present embodiment, the adhesive layer 150 is a silicone-based adhesive having a thermal conductivity of between 2.0 W/mK and 2.5 W/mK, and an elasticity of between 5 megapascal (Mpa) and 20 Mpa at room temperature. Alternatively, the circuit element 112 may be mounted on both the front surface and the back surface of the wiring board 111. For example, a film resistor may be mounted on the back surface of the wiring board 111. Alternatively, a recess for accommodating the circuit element 112 mounted on the back surface of the wiring board 111 may be formed on the front surface of the heatsink 120.

The heatsink 120 dissipates heat generated by the circuit element 112, which is mounted on the wiring board 111, outside the electronic control apparatus 100. The heatsink 120 is flat in shape so that the wiring board 111 can be fixed to the heatsink 120 through the adhesive layer 150. The heatsink 120 has a heat dissipation capability greater than that of the wiring board 111. It is preferable that the heatsink 120 have a high thermal conductivity, a low elasticity, and a linear expansion coefficient close to that of each of the wiring board 111 and the molding resin 140.

For example, in the present embodiment, the wiring board 111 has a linear expansion coefficient of about 7 ppm/° C., the molding resin 140 has a linear expansion coefficient of about 11 ppm/° C., and the heatsink 120 is formed with iron having a thermal conductivity of about between 60 W/mK and 70 W/mK, an elasticity of about 210 gigapascal (Gpa), and a linear expansion coefficient of about 12 ppm/° C. Since the heatsink 120, the wiring board 111, and the molding resin 140 have almost the same linear expansion coefficient, a stress due to a difference in a linear expansion coefficient therebetween can be reduced when a temperature change occurs. Accordingly, crack and detachment of the molding resin 140 from the wiring board 111 and the heatsink 120 can be reduced.

As described above, the heatsink 120 is partially exposed outside the molding resin 140. Specifically, the back surface of the heatsink 120 is not covered with the molding resin 140. In such an approach, although the heatsink 120 is formed with iron, which has a middle thermal conductivity, the heatsink 120 can suitably dissipate the heat generated by the circuit element 112 mounted on the wiring board 111. The manufacturing cost of the electronic control apparatus 100 can be reduced by using iron as a material for the heatsink 120, because iron is cheap.

The size and shape of the heatsink 120 can vary regardless of the size and shape of the wiring board 111. For example, the wiring board 111 and the heatsink 120 may have the same surface area, the same thickness, and the same shape. In the present embodiment, the heatsink 120 has the same shape as the wiring board 111 and has the surface area greater than of the wiring board 111, so that the whole wiring board 111 can be placed on the heatsink 120. Specifically, the heatsink 120 is 40 mm square, whereas the wiring board 111 is 35 mm square. In such an approach, the circuit board 110 can be easily positioned with respect to the heatsink 120. Further, the heatsink 120 can efficiently dissipate the heat from the circuit board 110.

The lead terminal 130 electrically connects the circuit board 110 to an external device (e.g., external ECU), so that the electronic control apparatus 100 can communicates with the external device. As illustrated in FIGS. 1-3, the first end of the lead terminal 130 is electrically connected to an electrical pad 114 formed on the circuit board 110 through a conductive wire 131 such as an aluminum wire. Alternatively, the first end of the lead terminal 130 may be electrically connected to the electrical pad 114 without the conductive wire 131, for example, by using a solder bump. Whereas the first end of the lead terminal 130 is covered with (i.e., encapsulated in) the molding resin 140, the second end of the lead terminal 130 is exposed outside the molding resin 140 to be connectable to the external device.

The molding resin 140 covers and protects at least the circuit board 110 and an electrical junction between the circuit board 110 and the lead terminal 130. In the present embodiment, the electronic control apparatus 100 has a half mold structure in which the whole circuit board 110, a part of the heatsink 120, and a part of the lead terminal 130 are integrally covered with the molding resin 140. Specifically, whereas the front surface and side surfaces of the heatsink 120 are covered with the molding resin 140, the back surface of the heatsink 120 is exposed outside the molding resin 140. Such a half mold structure allows the heat of the circuit board 110 to be directly dissipated outside the electronic control apparatus 100 through the heatsink 120 without through the molding resin 140. Thus, the heat can be efficiently dissipated from the circuit board 110.

For example, the molding resin 140 can be formed with thermoset resin having a linear expansion coefficient of about between 8 ppm/° C. and 12 ppm/° C. and an elasticity of about between 12 GPa and 25 Gpa at room temperature. In the present embodiment, the molding resin 140 is 50 mm square and formed with an epoxy-based resin having a linear expansion coefficient of about 11 ppm/° C.

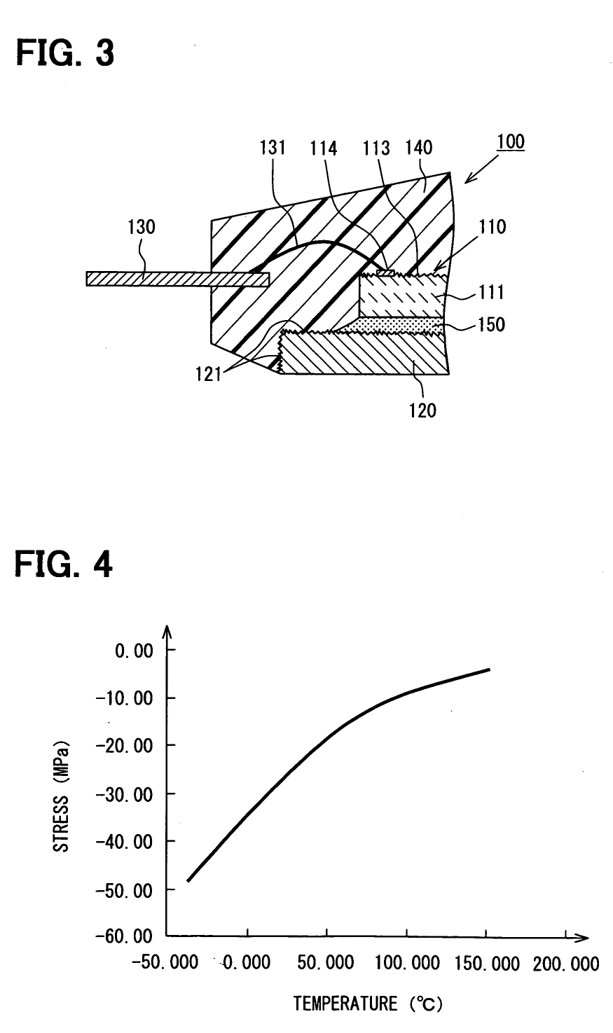

As shown in FIG. 3, a contact (i.e., covered) surface of the wiring board 111 to the molding resin 140 is roughened to produce a number of uneven portions 113 on the contact surface. The uneven portions 113 increase a contact surface area between the wiring board 111 and the molding resin 140. Likewise, a contact surface of the heatsink 120 to the molding resin 140 is roughened to produce a number of uneven portions 121 on the contact surface. The uneven portions 121 increase the contact surface area between the heatsink 120 and the molding resin 140.

Further, the uneven portions 113, 121 produce anchor effects that the wiring board 111 and the heatsink 120 to be anchored to the molding resin 140. Thus, adhesion of the molding resin 140 to the wiring board 111 and the heatsink 120 is improved so that the wiring board 111 and the heatsink 120 can be tightly attached to the molding resin 140. Thus, the molding resin 140 can be prevented from being cracked and detached from the wiring board 111 and the heatsink 120 without affecting characteristics of the circuit element 112 and reliability of connection of the circuit element 112 to the wiring board 111.

In the present embodiment, as shown in FIG. 3, the contact surface of the heatsink 120 to the adhesive layer 150 is also roughened to produce a number of uneven portions. In such an approach, the heatsink 120 is tightly attached to the circuit board 110 through the adhesive layer 150. Therefore, although the electronic control apparatus 100 has the half mold structure in which the part (i.e., back surface) of the heatsink 120 is exposed outside the molding resin 140, the circuit board 110 and the heatsink 120 can be reliably supported by the molding resin 140. The exposed surface (i.e., back surface) of the heatsink 120 may be also roughened to increase the exposed surface area in order to improve the heat dissipation efficiency.

In the present embodiment, both the contact surfaces of the circuit board 110 and the heatsink 120 to the molding resin 140 are entirely roughened. Alternatively, at least one of the contact surfaces of the circuit board 110 and the heatsink 120 to the molding resin 140 may be partially roughened.

The uneven portions 113, 121 can be produced by processing the surfaces of the circuit board 110 and the heatsink 120 by using a known roughening treatment such as a sandblasting treatment, an etching treatment (e.g., electrolytic etching, or chemical etching), or the like.

For example, the electronic control apparatus 100 is manufactured as follows:

First, the circuit board 110 and the heatsink 120 are prepared. In the present embodiment, the surfaces of the circuit board 110 and the heatsink 120 are roughened in this preparation process, for example, by an etching technique, in order to form the uneven portions 113, 121 on the surfaces of the circuit board 110 and the heatsink 120, respectively. The surface of the circuit board 110 is roughened, before or after the circuit element 112 is mounted on the wiring board 111. If the surface of the circuit board 110 is roughened before the circuit element 112 is mounted on the wiring board 111, the uneven portions 113 may be smoothed (i.e., removed) due to an insulating layer (e.g., solder resist layer) applied to the surface of the circuit board 110. Therefore, it is preferable that the uneven portions 113 maintain its own shape even after such an insulating layer is applied to the surface of the circuit board 110 to complete the circuit board 110.

After the preparation process is finished, a connection process is performed. In the connection process, the circuit board 110 is fixed on the heatsink 120 through the adhesive layer 150 so that the circuit board 110 and the heatsink 120 can be thermally connected to each other. Further, after or before the circuit board 110 is fixed on the heatsink 120, the lead terminal 130 and the circuit board 110 are electrically connected to each other through the conductive wire 131. In the present embodiment, after the circuit board 110 is fixed on the heatsink 120, the lead terminal 130 and the circuit board 110 are electrically connected to each other.

After the connection process is finished, a molding process is performed. In the molding process, the circuit board 110 and the junction between the circuit board 110 and the lead terminal 130 are integrally covered with the molding resin 140 by a transfer molding technique in such a manner that the lead terminal 130 and the heatsink 120 are partially exposed outside the molding resin 140. Then, the molding resin 140 is hardened so that the electronic control apparatus 100 can have the half molding structure.

It is preferable that a cleaning process be performed immediately before the molding process. In the cleaning process, the roughened surfaces (i.e., the uneven portions 113, 121) of the circuit board 110 and the heatsink 120 are cleaned by a plasma cleaning treatment, an ultraviolet (UV) ozone cleaning treatment, or the like. In the present embodiment, the cleaning process is performed before the molding process, and the roughened surfaces are cleaned by a plasma cleaning treatment. In such an approach, foreign matters (e.g., volatile component contained in the adhesive layer 150) adhered to the roughened surfaces of the circuit board 110 and the heatsink 120 are removed so that the uneven portions 113, 121 of the circuit board 110 and the heatsink 120 can return to their original shapes. Thus, the circuit board 110 and the heatsink 120 are tightly attached to the molding resin 140.

The present inventor has evaluated adhesion improvement caused by the roughened surface. Specifically, the present inventor have conducted a thermal test, in which a temperature of the electronic control apparatus 100 is changed in a range from minus 40 degrees Celsius (° C.) to plus 150° C. to measure stress exerted on a corner of the wiring board 111 in a direction perpendicular to the thickness direction of the wiring board 111. As can be seen from the result of the thermal test illustrated in FIG. 4, the stress reaches its peak value of 50 Mpa at minus 40° C.

The present inventor have investigated a relationship between adhesion of the heatsink 120 to the molding resin 140 and a surface roughness of the heatsink 120 at minus 40° C. The surface roughness is defined as a ratio of real surface area to apparent surface area. The apparent surface area is calculated by assuming that a surface is perfectly smooth, i.e., has no uneven portion. For example, it is assumed that apparent surface area of a predetermined surface portion of the heatsink 120 is 10 square millimeters. When the surface portion is roughed so that real surface area of the roughened surface portion becomes 25 square millimeters, the roughened surface portion has a surface roughness of 2.5 (i.e., 25/10).

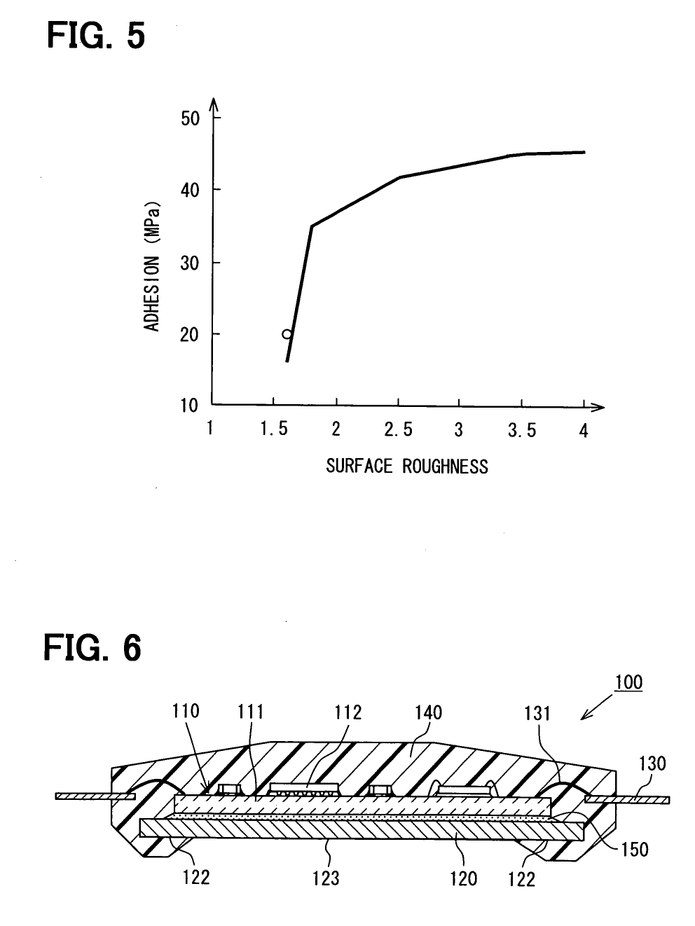

According to a result of the investigation, the circuit board 110 has an initial surface roughness of about 1.6. In other words, the circuit board 110 has some uneven portions, even before the roughening treatment to produce the uneven portion 113 is applied to the circuit board 110. As indicated by a circle in FIG. 5, when the surface roughness of the circuit board 110 is about 1.6, adhesion of the circuit board 110 to the molding resin 140 is about 20 Mpa. Likewise, the heatsink 120 has an initial surface roughness of about 1.6. In other words, the heatsink 120 has some uneven portions, even before the roughening treatment to produce the uneven portion 121 is applied to the heatsink 120. As indicated by a graph in FIG. 5, when the surface roughness of the heatsink 120 is about 1.6, adhesion of the heatsink 120 to the molding resin 140 is about 16 Mpa. As a result of application of a chemical etching treatment to the covered surface of the heatsink 120, the surface roughness of the heatsink 120 increases, and the adhesion of the heatsink 120 to the molding resin 140 increases accordingly. The same may be true of the circuit board 110. Therefore, as long as at least one of the covered surfaces of the circuit board 110 and the heatsink 120 is at least partially roughened, the adhesion of the molding resin 140 to the circuit board 110 and the heatsink 120 can be improved so that the molding resin 140 can be tightly attached to the circuit board 110 and the heatsink 120.

As can been seen from FIG. 5, when the surface roughness of the heatsink 120 is less than 1.8, the adhesion of the heatsink 120 to the molding resin 140 sharply changes with a change in the surface roughness of the heatsink 120. Therefore, if the surface roughness of the heatsink 120 is set less than 1.8, the adhesion of the heatsink 120 to the molding resin 140 may significantly vary according to a surface roughness change due to a manufacturing variation. The significant variation in the adhesion of the heatsink 120 to the molding resin 140 is undesirable from a quality control viewpoint.

In contrast, when the surface roughness of the heatsink 120 is greater than or equal to 1.8, the adhesion of the heatsink 120 to the molding resin 140 gradually changes with a change in the surface roughness of the heatsink 120. Therefore, even if the surface roughness change occur due to the manufacturing variation, the variation in the adhesion of the heatsink 120 to the molding resin 140 can be reduced by setting the surface roughness of the heatsink 120 greater than or equal to 1.8. Thus, a quality of the electronic control apparatus 100 can be stable.

Further, as the surface roughness of the heatsink 120 increases, the adhesion of the heatsink 120 to the molding resin 140 increases. Therefore, the heatsink 120 can be tightly attached to the molding resin 140 by setting the surface roughness of the heatsink 120 greater than or equal to 1.8. As can be seen from FIG. 5, when the surface roughness of the heatsink is set greater than or equal to 2.3, the adhesion of the heatsink 120 to the molding resin 140 exceeds 40 MPa, which is close to the peak value (i.e., 50 MPa) of the stress exerted on the corner of the wiring board 111 at minus 40° C. Therefore, it is preferable that the surface roughness of the heatsink 120 be set greater than or equal to 2.3 to efficiently prevent the molding resin 140 from being cracked and detached from the heatsink 120.

The present inventor has confirmed through experiment that when the surface roughness of the heatsink 120 is about 2.3 (i.e., when the adhesion of the heatsink 120 to the molding resin 140 is 40 MPa), there is no crack and detachment of the molding resin 140 even after the thermal test, in which the temperature changes from minus 40° C. to plus 150° C., is repeated three thousands times.

As shown in FIG. 5, when the surface roughness of the heatsink 120 is greater than 3.5, the adhesion of the heatsink 120 to the molding resin 140 changes very little with a change in the surface roughness of the heatsink 120. Further, as the surface roughness of the heatsink 120 is set greater, the cost of roughening the heatsink 120 increases. Furthermore, as the surface roughness of the heatsink 120 is set greater, the strength of the heatsink 120 decreases. Therefore, it is preferable that the surface roughness of the heatsink 120 be set less than is 3.5.

According to the present embodiment, at least one of the contact surfaces of the circuit board 110 and the heatsink 120 to the molding resin 140 is at least partially roughened to increase the contact surface area. In such an approach, the circuit board 110 and the heatsink 120 are tightly attached to the molding resin 140. Thus, the molding resin 140 is prevented from being cracked and detached from the circuit board 110 and the heatsink 120 without affecting characteristics of the circuit element 112 and reliability of connection between the circuit element 112 and the wiring board 111.

According to the present embodiment, the circuit board 110 is fixed to the heatsink 120 through the adhesive layer 150 to efficiently dissipated the heat from the circuit board 110. Further, the electronic control apparatus 100 has the half mold structure in which the heatsink 120 is partially exposed from the molding resin 140. The half mold structure allows the heat to be directly dissipated outside the electronic control apparatus 100 through the heatsink 120. In such an approach, the heatsink 120 can efficiently dissipate the heat, even when the heatsink 120 is not formed with an expensive material having a high thermal conductivity. Therefore, the electronic control apparatus 100 can be manufactured at low cost.

In the half mold structure, the heatsink 120 is partially exposed from the molding resin 140. Accordingly, the contact surface of the heatsink 120 to the molding resin 140 is exposed outside. Therefore, it may be likely that the molding resin 140 may be cracked and detached from the heatsink 120, as compared to a full mold structure in which a heatsink 120 is entirely encapsulated in the molding resin 140. According to the present embodiment, the contact surface is roughened to increase the contact surface area between the heatsink 120 and the molding resin 140. Thus, the heatsink 120 is tightly attached to the molding resin 140 and prevented from being cracked and detached from the heatsink 120. Since the heatsink 120 is partially exposed from the molding resin 140, the heat can be efficiently dissipated outside the electronic control apparatus 100. A resistance of the molding resin 140 to the clack and detachment can be improved by setting a difference in a linear expansion coefficient between the heatsink 120 and the molding resin 140 less than each of a difference in a linear expansion coefficient between the heatsink 120 and the molding resin 140 and a difference in a linear expansion coefficient between the circuit board 110 and the molding resin 140.

According to the present embodiment, the surfaces of the circuit board 110 and the heatsink 120 are roughened in the preparation process. Alternatively, the surfaces of the circuit board 110 and the heatsink 120 may be roughened in another process before the molding process (or cleaning process).

According to the present embodiment, the front and side surfaces of the heatsink 120 contacts and is encapsulated in the molding resin 140, and the back surface of the heatsink 120 is exposed from the molding resin 140. Alternatively, for example, the side surface of the heatsink 120 may be at least partially exposed from the molding resin 140 in addition to the back surface. In such an approach, the heat can be dissipated more efficiently. Alternatively, as shown in FIG. 6, a perimeter portion 122 of the back surface of the heatsink 120 may contact and be encapsulated in the molding resin 140, and a center portion 123, enclosed by the perimeter portion 122, of the back surface of the heatsink 120 may be exposed from the molding resin 140. In such an approach, the heatsink 120 is supported by the molding resin 140 from side to side and up and down, and the contact surface area between the heatsink 120 and the molding resin 140 is increased. Thus, the heatsink 120 is more tightly attached to the molding resin 140 so that the resistance of the molding resin 140 to the detachment from the heatsink 120 can be improved.

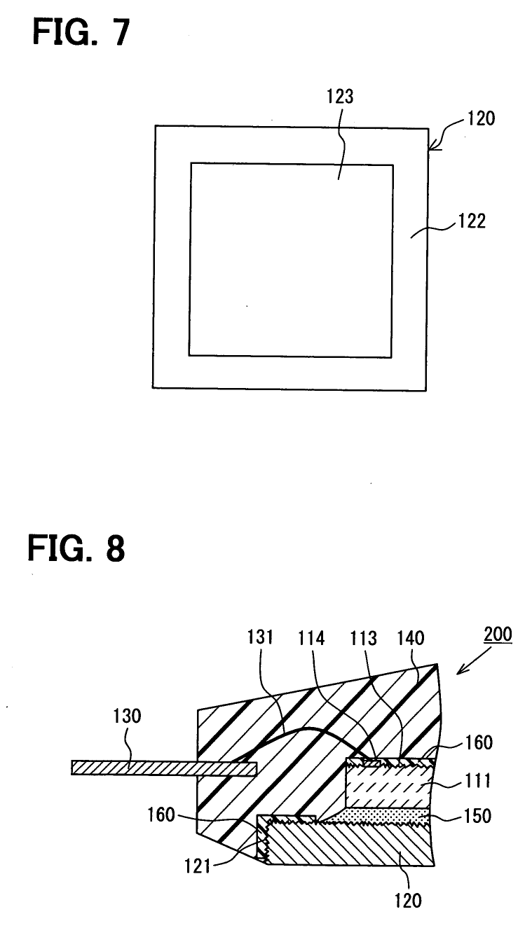

According to the structure shown in FIG. 6, as area of the perimeter portion 122 is increased, the detachment resistance of the molding resin 140 is improved. However, as the area of the perimeter portion 122 is increased, an area of the center portion 123 is reduced. Accordingly, the heat dissipation capacity of the heatsink 120 is reduced. To ensure an appropriate heat dissipation capacity, it is preferable that the area of the center portion 123 be greater than the perimeter portion 122, as shown in FIG. 7.

### Second Embodiment

An electronic control apparatus 200 according to a second embodiment of the present invention is described below with reference to FIG. 8. Differences between the electronic control apparatus 100, 200 are as follows.

In the electronic control apparatus 100, the roughened surfaces (i.e., uneven portions 113, 121) of the circuit board 110 and the heatsink 120 directly contact the molding resin 140. In contrast, in the electronic control apparatus 200, the roughened surfaces of the circuit board 110 and the heatsink 120 contact the molding resin 140 through a coupling layer 160 that increases an adhesion of the molding resin 140 to the roughened surfaces of the circuit board 110 and the heatsink 120.

For example, the coupling layer 160 can be formed with a coupling material that has an elasticity less than that of each of the circuit board 110, the heatsink 120, and the molding resin 140, or a coupling material that makes a chemical bond with the circuit board 110, the heatsink 120, and the molding resin 140. An example of such a coupling material is polyamide, polyimide, polyamide-imide, or the like. In the second embodiment, the coupling layer 160 is formed with polyamide, which is relatively cheap.

In a coupling layer forming process to form the coupling layer 160, the coupling material is diluted with a solvent to a desired consistency and then applied to the roughened surfaces of the circuit board 110 and the heatsink 120 by using a dispenser, for example. Typically, polyamide is diluted with a high polarity solvent. However, such a high polarity solvent can dissolve a resin component (e.g., organic binder) contained in conductive adhesive (e.g., silver paste) used as a conducting material for electrically, mechanically connecting the wiring board 111 and the circuit element 112. Further, such a high polarity solvent can dissolve a resin package of the circuit element 112 (e.g., tantalum capacitor). Therefore, if such a high polarity solvent is used to form the coupling layer 160, a junction resistance may increase, and a characteristic of the circuit element 112 may change.

According to the second embodiment, the coupling material is diluted with a low polarity solvent to form the coupling layer 160. In such an approach, the molding resin 140 can be tightly attached to the circuit board 110 and the heatsink 120 without affecting the characteristic of the circuit element 112 and the reliability of connection of the circuit element 112 to the wiring board 111. In the second embodiment, for example, diethylene glycol dimethyl ether is used as the solvent to dilute the coupling material.

In the cleaning process described in the first embodiment, the roughened surfaces of the circuit board 110 and the heatsink 120 can be cleaned by using the solvent used to dilute the coupling material. In such an approach, the manufacturing process of the electronic control apparatus 200 can be simplified.

The coupling layer forming process is performed, after the roughened surfaces are formed and before the molding process is performed. Like the cleaning process, it is preferable that the coupling layer forming process be performed immediately before the molding process. In such an approach, the adhesion of the molding resin 140 to the circuit board 110 and the heatsink 120 can be efficiently improved. Therefore, in the second embodiment, the coupling layer forming process is performed between the connection process and the molding process.

Generally, the circuit board 110 and the heatsink 120 are partially warped. Therefore, when the coupling material diluted with the solvent is applied to the circuit board 110 and the heatsink 120 to form the coupling layer 160 thereon, the coupling material may flow away from the warped portions of the circuit board 110 and the heatsink 120. As a result, since the warped portions of the circuit board 110 and the heatsink 120 may not be provided with the coupling layer 160, the adhesion of the molding resin 140 to the circuit board 110 and the heatsink 120 may be poor at the warped portions. The crack and detachment of the molding resin 140 may be caused from the warped portions of the circuit board 110 and the heatsink 120.

To prevent the above problem, according to the second embodiment, the covered surfaces of the circuit board 110 and the heatsink 120 are roughened to form the uneven portions 113, 121 thereon, and the coupling material is applied to the uneven portions 113, 121 of the circuit board 110 and the heatsink 120. In such an approach, the coupling material remains within the covered surfaces of the circuit board 110 and the heatsink 120 so that the covered surfaces can be surely provided with the coupling layer 160. Thus, the adhesion of the molding resin 140 to the circuit board 110 and the heatsink 120 is surely improved by the coupling layer 160 so that the molding resin 140 can be tightly attached to the circuit board 110 and the heatsink 120.

As described above, according to the second embodiment, the roughened surfaces (i.e., uneven portions 113, 121) of the circuit board 110 and the heatsink 120 contact the molding resin 140 through the coupling layer 160 that increases the adhesion of the molding resin 140 to the roughened surfaces. In such an approach, the molding resin 140 can be tightly attached to the circuit board 110 and the heatsink 120. Further, since the coupling material remains within the roughened surfaces, the coupling layer 160 can be surely formed on the roughen surfaces. Thus, the adhesion of the molding resin 140 is increased to surely prevent the crack and detachment of the molding resin 140.

According to the second embodiment, the coupling material is diluted with a low polarity solvent to form the coupling layer 160. In such an approach, the molding resin 140 can be tightly attached to the circuit board 110 and the heatsink 120 without affecting the characteristic of the circuit element 112 and the reliability of connection of the circuit element 112 and the wiring board 111.

According to the second embodiment, the coupling layer 160 is formed on each of the uneven portions 113, 121 of the circuit board 110 and the heatsink 120. Alternatively, the coupling layer 160 may be formed on at least one of the uneven portions 113, 121.

(Modifications)

The embodiments described above may be modified in various ways. In the above-described embodiments, the covered surfaces of the circuit board 110 and the heatsink 120 by the molding resin 140 are roughened to form the uneven portions 113, 121 that increase the adhesion of the molding resin 140 to the circuit board 110 and the heatsink 120. In short, the covered surfaces of the circuit board 110 and the heatsink 120 to the molding resin 140 are physically (i.e., mechanically) modified. Alternatively, the covered surfaces of the circuit board 110 and the heatsink 120 to the molding resin 140 can be chemically modified to increase the adhesion of the molding resin 140 to the circuit board 110 and the heatsink 120.

For example, the chemically modified surfaces can be formed by a UV ozone treatment, a corona treatment, a plasma treatment, an electron beam treatment, or the like. The chemically modified surfaces are activated so that intermolecular attraction force at the interface between the molding resin 140 and each of the circuit board 110 and the heatsink 120 can be increased. Thus, the adhesion of the molding resin 140 to the circuit board 110 and the heatsink 120 can be increased.

In the above-described embodiments, the electronic control apparatus 100, 200 have the half mold structure in which the heatsink 120 is partially exposed from the molding resin 140. Alternatively, the electronic control apparatus 100, 200 can have the full mold structure in which the heatsink 120 is fully covered with (i.e., encapsulated in) the molding resin 140. Even in the case of the full mold structure, due to the roughened surfaces, the molding resin 140 can be tightly attached to the circuit board 110 and the heatsink 120 without using an insulating material diluted with a high polarity solvent.

Therefore, the molding resin 140 can be prevented from being cracked and detached from the circuit board 110 and the heatsink 120 without affecting the characteristic of the circuit element 112 and the reliability of connection of the circuit element 112 to the wiring board 111. Even in the case of the full mold structure, the electronic control apparatus 100, 200 can efficiently dissipate the heat from the circuit board 110, because the circuit board 110 is placed on the heatsink 120.

Such changes and modifications are to be understood as being within the scope of the present invention as defined by the appended claims.

What is claimed is:

1. An electronic control apparatus comprising:
a circuit board that includes a circuit element mounted thereon;
a heat dissipation member that has front and back sides and dissipates heat from the circuit board placed on the front side;
an external terminal that has a first end electrically connected to the circuit board and a second end connectable to an external device; and
a molding resin that covers the circuit board and the first end of the external device,
wherein the second end of the external terminal is exposed outside the molding resin, and
wherein at least one of covered surfaces of the circuit board and the heat dissipation member is at least partially roughened to have a predetermined surface roughness.

2. The electronic control apparatus according to claim 1,
wherein the heat dissipation member is partially exposed outside the molding resin.

3. The electronic control apparatus according to claim 2,
wherein the back side of the heat dissipation member has a perimeter portion and a center portion enclosed by the perimeter portion,
wherein the perimeter portion is covered with the molding resin, and
wherein the center portion is exposed outside the molding resin.

4. The electronic control apparatus according to claim 3,
wherein an area of the center portion is greater than an area of the perimeter portion.

5. The electronic control apparatus according to claim 1,
wherein a linear expansion coefficient difference between the molding resin and the heat dissipation member is less than each of a linear expansion coefficient difference between the circuit board and the heat dissipation member and a linear expansion coefficient difference between the circuit board and the molding resin.

6. The electronic control apparatus according to claim 1,
wherein the surface roughness is defined as a ratio of real surface area to apparent surface area of the roughened surface,
wherein the apparent surface area is determined by assuming that the roughened surface is smooth, and
wherein the surface roughness is greater than or equal to 1.8.

7. The electronic control apparatus according to claim 6,
wherein the surface roughness is greater than or equal to 2.3.

8. The electronic control apparatus according to claim 6,
wherein the surface roughness is less than or equal to 3.5.

9. The electronic control apparatus according to claim 1,
wherein the circuit board is formed with a ceramic board.

10. The electronic control apparatus according to claim 1, further comprising:
a polymeric member interposed between the roughened surface and the molding resin,
wherein an adhesion of the polymeric member to the molding resin is greater than an adhesion of the roughened surface to the molding resin.

11. The electronic control apparatus according to claim 10,
wherein the polymeric member is a polyamide.

12. A method of manufacturing an electronic control apparatus comprising:
(a) preparing a circuit board with a circuit element mounted thereon and a heat dissipation member for dissipating heat from the circuit board;
(b) placing the circuit board on the heat dissipation member, the placing including electrically connecting the circuit board to a first end of an external terminal;
(c) modifying at least one of surface portions of the circuit board and the heat dissipation member to increase an adhesion of the at least one of surface portions to a molding resin; and
(d) integrally molding the circuit board and the first end of the external terminal with the molding resin in such a manner that the modified surface portion is covered with the molding resin, and a second end of the external terminal is exposed outside the molding resin.

13. The method according to claim 12,
wherein step (d) includes partially exposing the heat dissipation member outside the molding resin.

14. The method according to claim 12,
wherein step (c) includes roughening the at least one of surface portions of the circuit board and the heat dissipation member.

15. The method according to claim 14, further comprising:
cleaning the roughened surface portion before step (d).

16. The method according to claim 14, further comprising:
depositing a polymeric member on the roughened surface by using a low polarity solvent to dilute the polymeric member before step (d),
wherein the low polarity solvent exerts no influence on a characteristic of the circuit element and a reliability of connection of the circuit element to the circuit board.

17. The method according to claim 16,
wherein the polymeric member is a polyamide, and
wherein the low polarity solvent is diethylene glycol dimethyl ether.
